(19) United States
(12) Patent Application Publication
(10) Pub. No.: US 2014/0069498 A1
(43) Pub. Date: Mar. 13, 2014

(54) SOLAR CELL AND METHOD OF MANUFACTURING THE SAME

(71) Applicants: Jae Eock Cho, Daejeon (KR); Yong Hwa Lee, Seoul (KR); Dong Ho Lee, Daejeon (KR); Hyun Cheol Ryu, Daejeon (KR); Gang Il Kim, Seoul (KR); Deoc Hwan Hyun, Daejeon (KR)

(72) Inventors: Jae Eock Cho, Daejeon (KR); Yong Hwa Lee, Seoul (KR); Dong Ho Lee, Daejeon (KR); Hyun Cheol Ryu, Daejeon (KR); Gang Il Kim, Seoul (KR); Deoc Hwan Hyun, Daejeon (KR)

(73) Assignee: HANWHA CHEMICAL CORPORATION, Seoul (KR)

(21) Appl. No.: 14/110,557

(22) PCT Filed: Mar. 13, 2012
(86) PCT No.: PCT/KR2012/001814

§ 371 Date: Oct. 8, 2013

(30) Foreign Application Priority Data
May 30, 2011 (KR) 10-2011-0051111

(51) Int. Cl. H01L 31/0216; H01L 31/0224

(52) U.S. Cl. CPC H01L 31/02168; H01L 31/022425
USPC 136/256; 438/72

(57) ABSTRACT

Provided is a solar cell, including: a semiconductor substrate having a p-n junction; an antireflection film formed on at least one side of the semiconductor substrate; first electrodes formed on the antireflection film; and second electrodes covering the first electrodes, wherein only the first electrodes selectively penetrate the antireflection film and is thus connected with the semiconductor substrate by a punch through process.

### TECHNICAL FIELD

The present invention relates to a solar cell and a method of manufacturing the same, and, more particularly, to a solar cell which can minimize surface defects attributable to the contact of a semiconductor substrate with electrodes and which has very low electrode resistance, and a method of manufacturing the same.

### BACKGROUND ART

Silicon solar cells were developed in the 1950's, and have since been improved by decreasing the surface defects of the substrate with silicon surface passivation technology using a silicon oxide film, the passivation technology having started to be used in the field of microelectronics by in the 1980's, and thus greatly increasing voltage and current. As a result, the high-efficiency solar cell age was brought about.

Factors influencing the efficiency of a semiconductor-based inorganic solar cell, which is the most general solar cell, are largely classified into three types.

The first factor for increasing the efficiency of a solar cell is that a solar cell must be designed to have a structure which can maximize the absorption of light. For this purpose, in a crystalline silicon solar cell, the reflectance thereof is being decreased by texturing the surface thereof unevenly. The surface of a solar cell, observed with the naked eye, is dark blue. The reason for this is because the surface thereof is coated with an antireflection film in order to transmit the maximum amount of light into the solar cell. Further, the light receiving area of a solar cell must be secured to the highest degree by minimizing the area of electrodes.

The second factor for increasing the efficiency of a solar cell is that electrons and hole excited by light must not fall down to a ground state in order to produce power although light absorption is increased to the maximum. Since electrons and holes, called ‘carriers’, are recombined and then extinguished by the impurities existing in a substrate and the defects of the surface of a substrate, the lifespan of carriers must be increased by using high-purity silicon or by a gathering process for removing impurities and a passivation process for removing surface defects in order to generate electricity due to the movement of carriers to surface electrodes before the recombination thereof. Currently, a silicon nitride layer serves both as a passivation film for removing surface detects and an antireflection film. This silicon nitride layer is very advantageous in terms of cost reduction.

The third factor for increasing the efficiency of a solar cell is that the arrangement of electrodes and the selection of an electrode material must be considered in order to minimize various electrical resistance losses in the process of carriers moving and coming into contact with external electrodes because a solar cell is an electric device. In particular, since fishbone-type surface electrodes must minimize shading loss and simultaneously increase electrical conductivity, it is required to optimize the line width, number and the like thereof depending on device characteristics.

As described above, generally, a passivation layer of a semiconductor substrate also serves as an antireflection film. However, when metal electrodes are formed on the semiconductor substrate using a punch through process, the damage of the passivation layer serving to reduce surface defects in the semiconductor substrate cannot be avoided. Therefore, since the passivation layer is partially damaged in the process of forming the metal electrodes using a punch through process, surface defects causing the recombination of carriers increase, thus decreasing the efficiency of a solar cell. In order to overcome this problem, the increase in the surface defect attributable to the formation of metal electrodes must be minimized by forming the metal electrodes using local contact between the metal electrodes and the semiconductor substrate.

Further, in order to solve the above problem, UNSW (University of New South Wales) manufactured high-efficiency solar cells, such as PESC, PERC, PERL and the like, by patterning a passivation layer by lithography and then minimizing the area of contact electrodes and increasing the thickness of conductive electrodes (Zhao J, Wang A, Green M A, Ferrazza F. Novel 19.8% efficient “honeycomb” textured multicrystalline and 24.4% monocrystalline silicon solar cells. Applied Physics Letters 1998; 73: 1991-1993.). However, this method is not suitable to manufacture a low-price high-efficiency solar cell because the processes thereof are complicated and lithography is expensive.

As described above, in order to realize a local electrode structure, conventionally, methods of forming a pattern for forming electrodes by removing a passivation film using lithography, chemical etching or lasers have been used, but these methods are problematic in that manufacturing costs increase due to the increase in the number of processes, and thus it is difficult to commercialize these methods. That is, even though a local electrode structure is realized by these conventional methods, these conventional methods can be practically applied only when the efficiency of a solar cell is increased to such a degree that the efficiency thereof offsets and exceeds the increase in cost due to the introduction of the new processes, so it is difficult to apply these methods to the commercialization of a solar cell. Moreover, these methods are problematic in that the line width and thickness of metal electrodes decrease, so resistance increases, thereby causing the efficiency of a solar cell to decrease.

### DISCLOSURE OF INVENTION

### Technical Problem

Accordingly, the present invention has been made to solve the above-mentioned problems, and an object of the present invention is to provide a solar cell, which is manufactured by a simple printing process, which can minimize the damage of a passivation film due to electrodes and which has excellent electrical characteristics, and a method of manufacturing the same.

### Solution to Problem

In order to accomplish the above object, an aspect of the present invention provides a solar cell, including: a semiconductor substrate having a p-n junction; an antireflection film formed on at least one side of the semiconductor substrate; first electrodes formed on the antireflection film; and second electrodes covering the first electrodes, wherein only the first electrodes selectively penetrate the antireflection film and are thus connected with the semiconductor substrate by a punch through process.

The solar cell may include antireflection films formed on both sides thereof facing each other, each of the antireflection films is a single layer film or a two-layer film, and each of the antireflection films may include the first electrodes and the second electrodes formed thereon.

The both sides of the solar cell may include a light-receiving surface and a surface opposite to the light-receiving surface.

The first electrodes may be dot-shaped electrodes arranged at regular intervals. The second electrodes may be band-shaped electrodes which are arranged to be spaced apart from each other, and each of the band-shaped electrodes may connect two or more of the dot-shaped electrodes. Each of the first electrodes may have a dot diameter of 30˜300 μm.

Both of the first electrodes and the second electrodes may be band-shaped electrodes. In this case, each of the first electrodes may have a width of 30˜300 μm, and each of the second electrodes may have a width of 50˜1000 μm.

Another aspect of the present invention provides a method of manufacturing a solar cell, including: forming an antireflection film on at least one side of a semiconductor substrate having a p-n junction; applying a first electrode material penetrating the antireflection film at the time of heat treatment onto the antireflection film to form first electrodes; applying a second electrode material not penetrating the antireflection film at the time of heat treatment onto the first electrodes to form second electrodes covering the first electrodes; and heat-treating the semiconductor substrate provided with the first electrodes and the second electrodes to selectively connect only the first electrodes of the first electrodes and the second electrodes with the semiconductor substrate.

In the forming the antireflection film, the one side of the semiconductor substrate may be a light-receiving surface, and an antireflection film may also be formed on a surface opposite to the light-receiving surface.

In the forming the first electrodes and in the forming the second electrodes, the first electrodes and the second electrodes may be formed on the antireflection film formed on the light-receiving surface of the solar cell and on the antireflection film formed on the surface opposite to the light-receiving surface thereof, respectively.

The forming the first electrodes and the forming the second electrodes may be each independently performed by screen printing, inkjet printing, offset printing or aerosol printing.

In the forming the first electrodes, the first electrodes may be dot-shaped electrodes arranged at regular intervals. The first electrodes may be dot-shaped electrodes having a dot diameter of 30˜300 μm.

In the forming the second electrodes, the second electrodes may be band-shaped electrodes which are arranged to be spaced apart from each other, and each of the band-shaped electrodes may connect two or more of the dot-shaped electrodes.

In the forming the first electrodes, the first electrodes may be dot-shaped electrodes having a width of 30˜300 μm. In the forming the second electrodes, the second electrodes may be band-shaped electrodes having a width of 50˜1000 μm.

In the heat-treating the semiconductor substrate, the heat treatment may be performed at a temperature of 100˜900° C.

Each of the first electrodes may include lead glass frit containing lead oxide or lead-free glass frit containing bismuth oxide and boron oxide. Each of the second electrodes may include silica-based glass frit or phosphate-based glass frit not containing boron (B), bismuth (Bi) and lead (Pb).

### Advantageous Effects of Invention

As described above, the solar cell according to the present invention is advantageous in that the surface defect caused by the damage of a passivation layer can be minimized by partial contact or local contact, thus minimizing the extinguishment of carriers attributable to the recombination thereof, in that passivation layers are respectively provided on the light-receiving surface of the solar cell and the opposite surface thereof, thus minimizing the loss of photoelectric current attributable to surface defects, and in that first electrodes formed on a semiconductor substrate are covered with second electrodes, so that serial resistance decreases, thereby increasing the photoelectric efficiency of the solar cell.

The method of manufacturing a solar cell according to the present invention is advantageous in that, since it is not required to form an electrode pattern in multiple stages using an expensive apparatus, manufacturing cost can be reduced, inexpensive solar cells can be produced in large amounts, can be minimized by a simple printing process, and electrodes, which can minimize the damage of a passivation layer and have low serial resistance, can be formed, and in that passivation layers are respectively provided on the light-receiving surface of the solar cell and the opposite surface thereof, thus minimizing the loss of photoelectric current attributable to surface defects.

### BRIEF DESCRIPTION OF DRAWINGS

The above and other objects, features and advantages of the present invention will become apparent from the following description of preferred embodiments given in conjunction with the accompanying drawings, in which:

FIG. 1 is a cross-sectional view showing a solar cell according to an embodiment of the present invention;

FIG. 2 is a perspective view showing a solar cell according to an embodiment of the present invention;

FIG. 3 is a perspective view showing a solar cell according to another embodiment of the present invention;

FIG. 4 is a cross-sectional view showing a solar cell according to still another embodiment of the present invention;

FIG. 5 is a process view showing a method of manufacturing a solar cell according to an embodiment of the present invention;

FIG. 6 is a process view showing a method of manufacturing a solar cell according to another embodiment of the present invention; and

FIG. 7 is a cross-sectional view showing a solar cell according to still another embodiment of the present invention.

### DETAILED DESCRIPTION OF MAIN ELEMENTS

100: semiconductor substrate having p-n junction
200, 500: antireflection film
101: p-type impurity doped region
102: n-type impurity doped region
300, 600: first electrode
301, 601: first electrode
400, 700: second electrode
401, 701: second electrode
W₁: width of first electrode
W₂: width of second electrode

### MODE FOR THE INVENTION

Hereinafter, preferred embodiments of the present invention will be described in detail with reference to the accompanying drawings. The following drawings are provided for those skilled in the art as examples in order to sufficiently explain the technical idea of the present invention. Therefore, the present invention may be modified in various forms without being limited to the following drawings, and these following drawings may be exaggerated to clearly explain the technical idea of the present invention. Further, throughout the accompanying drawings, the same reference numerals are used to designate the same or similar components.

In this case, it means that the technical and scientific terms used in the present specification are generally understood by those skilled in the art as long as they are not differently defined. Further, in the description of the present invention, when it is determined that the detailed description of the related art would obscure the gist of the present invention, the description thereof will be omitted.

A solar cell according to the present invention includes: a semiconductor substrate having a p-n junction; an antireflection film formed on at least one side of the semiconductor substrate; and first electrodes and second electrodes formed on the antireflection film, wherein the first electrodes penetrate the antireflection film to be connected with the semiconductor substrate, and the second electrodes do not penetrate the antireflection film and are formed on the first electrodes to cover the first electrodes.

The solar cell of the present invention means a semiconductor-based solar cell. The semiconductor-based solar cell includes: a standard solar cell in which electrodes are separately located at the light-receiving side and back side thereof; a backside solar cell in which all electrodes are located at the back side thereof, such as IBC (interdigitated back-contact), MWT (metal wrap-through), EWT (emitter wrap-through) or the like; and a bifacial solar cell.

In the solar cell of the present invention, the semiconductor substrate includes: a group IV semiconductor substrate containing silicon (Si), germanium (Ge) or silicongermanium (SiGe); a group III-V semiconductor substrate containing gallium-arsenic (GaAs), indium-phosphorus (InP) or gallium-phosphorus (GaP); a group II-VI semiconductor substrate containing cadmium sulfide (CdS) or zinc telluride (ZnTe); or a IV-VI semiconductor substrate containing lead sulfide (PbS).

Crystallographically, the semiconductor substrate includes a monocrystalline substrate, a polycrystalline substrate or an amorphous substrate.

Further, the semiconductor substrate includes a semiconductor substrate including a substrate doped with impurities to have a selective emitter structure and a back surface field layer for forming a backside electric field. The semiconductor substrate includes a semiconductor substrate whose surface is unevenly textured by etching.

The semiconductor substrate having a p-n junction means a semiconductor substrate in which a region doped with first conductive impurities and a region doped with second conductive impurities complementary to the first conductive impurities face each other to form a depletion layer.

The semiconductor substrate having a p-n junction includes a semiconductor substrate including a doping layer doped with second conductive impurities, the doping layer being formed by applying thermal energy onto a semiconductor substrate doped with first conductive impurities in the presence of second conductive impurities. The doping layer includes a surface layer of the semiconductor substrate.

For example, the first conductive impurities are p-type impurities containing boron (B) or aluminum (Al), and the second conductive impurities are n-type impurities containing phosphorus (P) or germanium (Ge).

One side of the semiconductor substrate, on which an antireflection film is formed, includes a light-receiving surface, a surface facing the light-receiving surface and a lateral surface of the light-receiving surface. The antireflection film is formed on at least one side of the semiconductor substrate. Therefore, the antireflection film may be formed on one or more selected from the light-receiving surface, the surface facing the light-receiving surface and the lateral surface of the light-receiving surface.

In the description of the present invention, the antireflection film serves both to prevent light introduced into the solar cell from being discharged to the outside of the solar cell and to passivate the surface of the semiconductor substrate by reducing surface defects acting as a trap site of electrons.

When the antireflection and passivation are performed by a single material, the antireflection film may be a single layer film, and, when the antireflection and passivation are performed by different materials from each other, the antireflection film may be a multilayer film.

However, even when the antireflection and passivation are performed by a single material, the antireflection film may be a multilayer film in order to maximize the antireflection and to effectively passivate the surface of the semiconductor substrate by reducing surface defects.

Concretely, the antireflection film may be any one single layer film selected from a semiconductor nitride film, a semiconductor oxide film, a hydrogen-containing semiconductor nitride film, a nitrogen-containing semiconductor oxide film, an Al₂O₃ film, a MgF₂ film, a ZnS film, a TiO₂ film and a CeO₂ film, and may be a multilayer film formed by laminating two or more single layer films selected therefrom.

For example, in a silicon solar cell, a single-layer antireflection film may be selected from a silicon nitride film, a hydrogen-containing silicon nitride film, a silicon oxynitride film, and a silicon oxide film, and a multilayer antireflection film may be a multilayer film formed by laminating two or more single layer films selected from a silicon nitride film, a hydrogen-containing silicon nitride film, a silicon oxynitride film, a silicon oxide film, an Al₂O₃ film, a MgF₂ film, a ZnS film, a TiO₂ film and a CeO₂ film.

The first electrodes penetrating the antireflection film are physically brought into contact with the semiconductor substrate by the interface reaction of the first electrodes with the antireflection film. That is, the first electrodes are brought into contact with the semiconductor substrate by a punch through phenomenon. For the specific mechanism related to the punch through phenomenon refer to the paper [J. Hoomstra, et al., 31st IEEE PVSC Florida 2005].

Concretely, the penetration of the first electrodes into the antireflection film means that the first electrode material applied on the antireflection film undergoes oxidation-reduction reaction by thermal energy on the interface between the first electrode material and the antireflection film to etch the antireflection film, and the conductive material included in the first electrode material is melted and recrystallized, and thus the first electrode material comes into contact with the semiconductor substrate along the region in which the antireflection film is etched.

For example, the first electrode material includes glass frit etching the antireflection film by the interface reaction, and includes a conductive metal material penetrating the etched antireflection film by melting and recrystallization to make a low-resistance passage.

Typical examples of the conductive metal material included in the first electrode may include one or more selected from silver (Ag), copper (Cu), titanium (Ti), gold (Au), tungsten (W), nickel (Ni), aluminum (Al), chromium (Cr), molybdenum (Mo), platinum (Pt), lead (Pb), palladium (Pd), and alloys thereof. Here, in terms of low melting point and excellent electrical conductivity, it is preferred that the conductive material be silver (Ag), copper (Cu), nickel (Ni), aluminum (Al) or an alloy thereof. As the glass frit included in the first electrode and etching the antireflection film, lead glass containing lead oxide or lead-free glass containing bismuth oxide and boron oxide, which is commonly used to form an electrode of a solar cell, may be used. Examples of the lead glass frit may include one or more selected from PbO—SiO₂—B₂O₃—Al₂O₃ glass frit, PbO—SiO₂—B₂O₃—Al₂O₃—ZrO₂ glass frit, PbO—SiO₂—B₂O₃—Al₂O₃—ZnO glass frit, and PbO—SiO₂—B₂O₃—Al₂O₃—ZnO—TiO₂ glass frit. Example of the lead-free glass frit may include Bi₂O₃—ZnO—SiO₂—B₂O₃—Al₂O₃ glass frit, Bi₂O₃—SrO—SiO₂—B₂O₃—Al₂O₃ glass frit, Bi₂O₃—ZnO—SiO₂—B₂O₃—La₂O₃—Al₂O₃ glass frit, Bi₂O₃—ZnO—SiO₂—B₂O₃—TiO_{2 glass frit, Bi}₂O₃—SiO₂—B₂O₃—SrO glass frit, and Bi₂O₃—SiO₂—B₂O₃—ZnO—SrO glass frit. In this case, the lead glass frit or the lead-free glass frit may further contain one or more additives selected from Ta₂O₅, Sb₂O₅, HfO₂, 1n₂O₃, Ga₂O₃, Y₂O₃ and Yb₂O₃. It is preferred that the first electrode include 3˜5 wt % of the lead glass frit or the lead-free glass frit.

The connection of the first electrode with the semiconductor substrate means that the conductive material included in the first electrode is physically brought into contact with the semiconductor substrate and is electrically connected with the semiconductor substrate. The region of the semiconductor substrate connected with the first electrode is a region of the semiconductor substrate doped with the first conductive impurities or a region of the semiconductor substrate doped with the second conductive impurities.

In this case, the region of the semiconductor substrate doped with the first conductive impurities or the second conductive impurities includes a region of the semiconductor substrate locally densely-doped with the same type of impurities, and the region of the semiconductor substrate locally densely-doped with the same type of impurities includes a region in which a selective emitter is formed and a region in which a backside electric field is formed.

The second electrode is formed on the first electrode and the antireflection film such that the first electrode covers the second electrode. The meaning that the second electrode covers the first electrode means that the entire surface of the first electrode is covered with the second electrode. The entire surface of the first electrode means a surface of the first electrode, which does not come into contact with the semiconductor substrate, and the surface of the first electrode include a top surface thereof and a lateral surface thereof.

As described above, the second electrode does not penetrate the antireflection film and is directly formed on the antireflection film, whereas the first electrode penetrates the antireflection film to come into contact with the semiconductor substrate. In this case, the meaning that the second electrode does not penetrate the antireflection film means that the second electrode material does not react with the antireflection film at the interface therebetween, and that the punch through phenomenon of the antireflection film attributable to the second electrode material does not occur even when thermal energy is applied.

Concretely, the meaning that the second electrode does not penetrate the antireflection film means that the oxidation-reduction reaction between the second electrode material and the antireflection film does not occur even when the second electrode material is applied on the first electrode material and then thermal energy is applied to the region on which the second electrode material is applied.

That is, the meaning that the second electrode does not penetrate the antireflection film means that the oxidation-reduction reaction between the second electrode material and the antireflection film does not occur, or the melting and crystallization of the second electrode material does not occur.

Preferably, the second electrode includes glass frit which does not react with the antireflection film at the interface therebetween, and a conductive metal material.

The glass frit included in the second electrode does not react with the antireflection film at the interface therebetween, and serves to improve the physical adhesivity of the second electrode and to increase the interfacial adhesion between the second electrode and the semiconductor substrate and the interfacial adhesion between the second electrode and the first electrode.

It is preferred that the conductive metal material included in the second electrode be a conductive metal material which can be densified by the thermal energy applied to punch through the first electrode and whose particles are grown thereby.

Typical examples of the conductive material included in the second electrode may include one or more selected from silver (Ag), copper (Cu), titanium (Ti), gold (Au), tungsten (W), nickel (Ni), chromium (Cr), molybdenum (Mo), platinum (Pt), lead (Pb), palladium (Pd), and alloys thereof. It is preferred that the glass frit, which is included in the second electrode and does not etch the antireflection film, be commonly used silica-based glass frit or phosphate-based glass frit which does not contain boron (B), bismuth (Bi) and lead (Pb). It is more preferred that the glass frit included in the second electrode is silica-based glass frit or phosphate-based glass frit which has a glass transition temperature 1.2˜2 times of that of the glass frit included in the first electrode and does not contain boron (B), bismuth (Bi) and lead (Pb).

The silica-based glass frit includes SiO₂, as a network forming component, and one or more selected from Li₂O, Na₂O, K₂O, MgO, CaO, BaO, SrO, ZnO, Al₂O₃, TiO₂, ZrO₂, Ta₂O₅, Sb₂O₅, HfO₂, In₂O₃, Ga₂O₃, Y₂O₃ and Yb₂O₃. The phosphate-based glass frit is vanadium-phosphate-based glass fit (P₂O₅—V₂O₅) or zinc-antimony-phosphate-based glass frit (P₂O₅—ZnO—Sb₂O₃). The phosphate-based glass frit may include one or more selected from K₂O, Fe₂O₃, Sb₂O₃, ZnO, TiO₂, Al₂O₃ and WO₃. In this case, it is preferred that the second electrode include 3˜5 wt % of the silica-based glass frit or the phosphate-based glass frit.

As described above, the solar cell according to the present invention is configured such that electrodes collecting electrons and holes produced by light irradiation include the first electrode and the second electrode.

The electrodes collecting electrons and holes include a finger electrode and/or a bus bar electrode.

In this case, the solar cell may further include a soldering layer for making a solar cell module connecting two or more solar cells in series or in parallel to each other on the electrodes including the first electrode and the second electrode. Specifically, in order to connect electrodes of two or more solar cells in series or in parallel to each other, the electrodes are attached to each other by soldering the electrodes with a conductive ribbon. Thus, the soldering layer is formed on the electrodes to conduct the soldering.

Concretely, the soldering layer serves to improve the adhesion between the conductive ribbon and the electrodes and the wettability of a solder material at the time of soldering the electrodes including the first electrode and the second electrode with the conductive ribbon.

As the conductive ribbon, a conductive ribbon commonly used to make a solar cell module may be used. As an example of the conductive ribbon, there is a copper ribbon plated with a solder material such as tin, lead or silver. The soldering layer is sufficient as long as it is a soldering layer generally used to improve the adhesion between the soldering layer and the solder material and the wettability of the solder material at the time of making a solar cell module. The soldering layer may be appropriately selected in consideration of the solder material.

However, the solar cell module may be made using a thermocurable, photocurable or chemically-curable conductive adhesive instead of soldering.

Hereinafter, the present invention will be described in detail, assuming that a semiconductor substrate containing p-type impurities is doped with n-type impurities as a surface layer to form a semiconductor substrate having a p-n junction.

FIG. 1 is a cross-sectional view showing a solar cell according to an embodiment of the present invention

As shown in FIG. 1, a semiconductor substrate 100 is provided with a junction plane (dotted line of FIG. 1) of a impurity doped region 101 and an n-type impurity doped region 102.

As shown in FIG. 1, the solar cell of the present invention includes: a semiconductor substrate 100 including a p-type impurity doped region 101 and an n-type impurity doped region 102 as an emitter layer; an antireflection film 200 formed on the emitter layer of the semiconductor substrate 100; first electrodes 300 penetrating the antireflection film 200 and thus connecting with the emitter layer; and second electrodes 400 covering the first electrodes.

FIG. 1 shows a solar cell provided with front electrodes including the first electrodes 300 and the second electrodes 400. Here, the first electrodes 300, which are electrodes penetrating the antireflection film 200 and thus connecting with the emitter layer, are adopted to minimize the damage of the antireflection film 200 and to be electrically connected with the emitter layer. The second electrodes 400 are adopted to reduce the increase in resistance caused by the ultrafine structure of the first electrodes 300.

As shown in FIG. 1, the solar cell according to the present invention is characterized in that the damage of the antireflection film 200 is minimized by the first electrodes 300, and the first electrodes 300 are electrically connected with the semiconductor substrate, and thus surface defects acting as recombination sites are reduced, and in that it is possible to prevent photocurrent from being extinguished. Moreover, the solar cell according to the present invention is characterized in that the damage of the antireflection film 200 is minimized by the second electrodes 400 covering the first electrodes, and resistance becomes very low, thus minimizing the loss of electrical resistance.

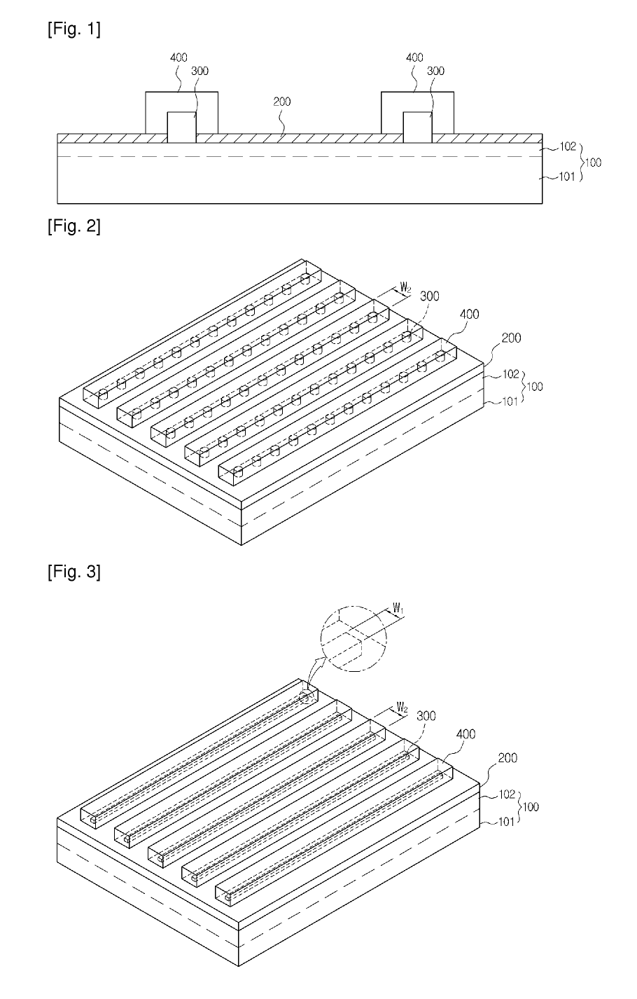

FIG. 2 is a perspective view showing the structure of the first electrodes of a solar cell according to an embodiment of the present invention, and FIG. 3 is a perspective view showing the structure of the first electrodes of a solar cell according to another embodiment of the present invention.

As shown in FIG. 2, the first electrodes 300 are regularly-arranged dot-shaped electrodes. The dot may be a circular dot, elliptical dot, tetragonal dot or polygonal dot.

As shown in FIG. 2, based on one unit including a plurality of dots arranged along a straight line and spaced apart from each other, it is preferred that two or more units are arranged at regular intervals and spaced apart from each other, and it is more preferred that two or more units are arranged in parallel with each other and spaced apart from each other.

When the first electrodes 300 are dot-shaped electrodes, the second electrodes 400 are a plurality of band-shaped electrodes spaced apart from each other, and each of the band-shaped electrodes covers two or more dot-shaped electrodes.

More concretely, as shown in FIG. 2, the second electrodes 400 are band-shape electrodes each covering each of the units constituting the first electrodes 300.

The first electrodes 300 may have a dot diameter of 30˜300 μm. In this dot diameter, the first electrodes 300 can be stably connected with the semiconductor substrate 100 by a punch through process, and the damage of the antireflection film can be minimized.

The second electrodes 400, which are formed on the first electrodes 300 and which are band-shaped electrodes covering the plurality of dot-shaped electrode arranged along a straight line and spaced apart form each other, may have a width (W₂) of 50˜1000 μm. In this width, the decrease in light-receiving area attributable to the second electrodes 400 can be minimized, and the increase in resistance attributable to the first electrodes 300 can be lowered. Concretely, in this width, front electrodes consisting of the first electrodes 300 and the second electrodes 400 can have a resistance of 3˜6×10⁻⁶ Ωcm.

FIG. 3 is a perspective view showing a solar cell including both first and second electrodes having a band shape. As shown in FIG. 3, the first electrodes 300 are band-shaped electrodes arranged in parallel with each other and spaced apart from each other, and the second electrodes 400 are band-shaped electrodes covering the band-shaped first electrodes 300, respectively.

It is preferred that the first electrodes have a width (W₁) of 30-300 μm. In this width, the first electrodes 300 are connected with the semiconductor substrate 100 in the shape of a continuous line, and the damage of the antireflection film 200 is minimized. Meanwhile, it is preferred that the second electrodes have a width (W₂) of 30˜300 μm, similarly to the case of the dot-shaped first electrode.

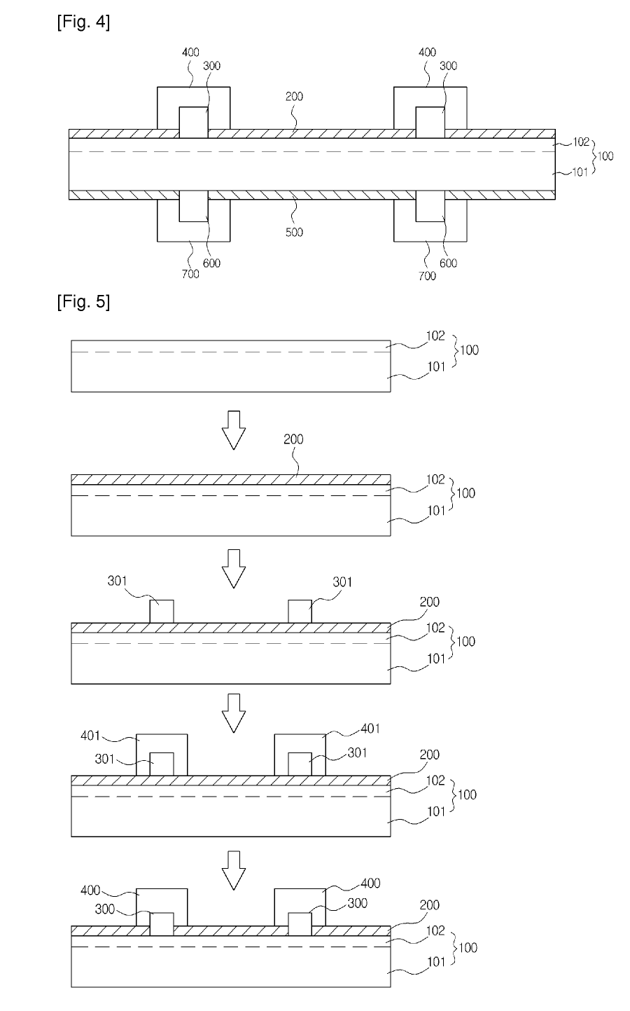

FIG. 4 is a cross-sectional view showing a solar cell according to still another embodiment of the present invention. As shown in FIG. 4, the solar cell according to this embodiment is characterized in that antireflection films 200 and 500 are respectively formed on the light-receiving surface of the solar cell and the opposite surface (back surface) thereof, thus effectively preventing the loss of photocurrent attributable to recombination.

The solar cell, similarly to the case of being described based on FIGS. 1 to 3, is provided on the back surface thereof with first electrodes 600, which penetrate the back antireflection film 500 to be connected with the p-type impurity doped region (including a back surface field region), and second electrodes 700, which do not penetrate the back antireflection film and cover the first electrodes 600. The first electrodes 600 and second electrodes 700 constitute back electrodes.

In this case, the back electrodes may have the same shape as the local contact electrodes described based on FIGS. 2 to 3. Further, the back electrodes may include dot-shaped or band-shaped first electrodes 300 and film-type second electrodes 400 covering the dot-shaped or band-shaped first electrodes 300.

FIG. 5 is a process view showing a method of manufacturing a solar cell according to the present invention. In the method of manufacturing a solar cell according to the present invention, first electrodes before heat treatment are called first printed electrodes, and second electrodes before heat treatment are called second printed electrodes. As shown in FIG. 5, the method of manufacturing a solar cell according to the present invention includes the steps of: forming an antireflection film 200 on at least one side of a semiconductor substrate 100 having a p-n junction; applying a first electrode material penetrating the antireflection film 200 at the time of heat treatment onto the antireflection film 200 to form first electrodes 301 (first printed electrodes); applying a second electrode material not penetrating the antireflection film 200 at the time of heat treatment onto the first electrodes 301 to form second electrodes 401 (second printed electrodes) covering the first electrodes 301; and heat-treating the semiconductor substrate 100 provided with the first electrodes 301 (first printed electrodes) and the second electrodes 401 (second printed electrodes) to selectively connect only the first electrodes 301 (first printed electrodes) of the first electrodes 301 (first printed electrodes) and the second electrodes 401 (second printed electrodes) with semiconductor substrate 100.

The antireflection film 200 may be any one single layer film selected from a semiconductor nitride film, a semiconductor oxide film, a hydrogen-containing semiconductor nitride film, a nitrogen-containing semiconductor oxide film, an Al₂O₃ film, a MgF₂ film, a ZnS film, a TiO₂ film and a CeO₂ film, and may be a multilayer film formed by laminating two or more single layer films selected therefrom. For example, in a silicon solar cell, the antireflection film 200 may be any one single layer films elected from a silicon nitride film, a hydrogen-containing silicon nitride film, a silicon oxynitride film, a silicon oxide film, an Al₂O₃ film, a MgF₂ film, a ZnS film, a TiO₂ film and a CeO₂ film, and may be a multilayer film formed by laminating two or more single layer films selected therefrom.

The antireflection film 200 may be formed by a film forming process generally used in semiconductor passivation. For examples, the antireflection film 200 may be formed by at least one selected from physical vapor deposition (PVD), chemical vapor deposition (CVD), plasma enhanced chemical vapor deposition (PECVD) and thermal evaporation.

After the formation of the antireflection film 200, the first electrodes 301 (first printed electrodes) are formed on the antireflection film 200. The first electrodes 301 (first printed electrodes) may be formed by applying a first electrode material onto the antireflection film, particularly, by printing the first electrode material on the antireflection film.

It is preferred that the printing of the first electrodes 301 (first printed electrodes) be performed by at least one selected from screen printing, gravure printing, offset printing, roll to roll printing, ink-jet printing, and aerosol printing. In terms of process cost and mass production, it is more preferred that the printing of the first electrodes 301 (first printed electrodes) be performed by screen printing.

As described above, the first electrode material includes glass frit etching the antireflection film with the interface reaction between the first electrode material and the antireflection film using thermal energy for a punch through process, and conductive metal particles penetrating the antireflection film as they melt and recrystallize

As the glass frit for etching, general glass frit used to form front electrodes by a punch through process at the time of manufacturing a conventional solar cell may be used. Further, as the glass frit for etching, lead glass containing lead oxide and lead-free glass containing bismuth oxide and boron oxide, each of which produces a stable glassy phase during the interface reaction between the first electrodes and the antireflection film, and maintains sufficient low viscosity and has excellent contact strength, may be used. Examples of the lead glass frit may include one or more selected from PbO—SiO₂—B₂O₃—Al₂O₃ glass frit, PbO—SiO₂—B₂O₃—Al₂O₃—ZrO₂ glass frit, PbO—SiO₂—B₂O₃—Al₂O₃—ZnO glass frit, and PbO—SiO₂—B₂O₃—Al₂O₃—ZnO—TiO₂ glass frit. Example of the lead-free glass frit may include Bi₂O₃—ZnO—SiO₂—B₂O₃—Al₂O₃ glass frit, Bi₂O₃—SrO—SiO₂—B₂O₃—Al₂O₃ glass frit, Bi₂O₃—ZnO—SiO₂—B₂O₃—La₂O₃—Al₂O₃ glass frit, Bi₂O₃—ZnO—SiO₂—B₂O₃—TiO₂ glass frit, Bi₂O₃—SiO₂—B₂O₃—SrO glass frit, and Bi₂O₃—SiO₂—B₂O₃—ZnO—SrO glass frit. In this case, the lead glass frit or the lead-free glass frit may further contain one or more additives selected from Ta₂O₅, Sb₂O₅, HfO₂, In₂O₃, Ga₂O₃, Y₂O₃ and Yb₂O₃

As the conductive metal particles included in the first electrode material, general conductive metal particles used to form front electrodes by a punch through process at the time of manufacturing a conventional solar cell may be used. Examples of the conductive metal particles included in the first electrodes may include one or more selected from silver (Ag), copper (Cu), titanium (Ti), gold (Au), tungsten (W), nickel (Ni), aluminum (Al), chromium (Cr), molybdenum (Mo), platinum (Pt), lead (Pb), palladium (Pd), and alloys thereof. Here, in terms of low melting point and excellent electrical conductivity, it is preferred that the conductive material be silver (Ag), copper (Cu), nickel (Ni), aluminum (Al) or an alloy thereof.

It is preferred that the first electrodes include 3˜5 wt % of the lead glass frit or the lead-free glass frit.

After the formation of the first electrodes 301, the second electrodes 401 are formed on the first electrodes 301 to cover the first electrodes. The second electrodes 401, similarly to the first electrodes 301, may be formed by applying a second electrode material onto the first electrodes 301 or by printing the second electrode material on the first electrodes 301.

Therefore, the method of manufacturing a solar cell according to the present invention is characterized in that a solar cell having ultrafine contact electrodes and excellent electrical conductivity can be manufactured by two-step printing and heattreatment without using expensive equipment and performing complicated processes.

It is preferred that the printing of the second electrodes 401, similarly to the printing of the first electrodes 301, be performed by at least one selected from screen printing, gravure printing, offset printing, roll to roll printing, ink-jet printing, and aerosol printing. In terms of process cost and mass production, it is more preferred that the printing of the second electrodes 401 be performed by screen printing.

As described above, the second electrode material included in the second electrodes includes the conductive metal particles one or more selected from silver (Ag), copper (Cu), titanium (Ti), gold (Au), tungsten (W), nickel (Ni), aluminum (Al), chromium (Cr), molybdenum (Mo), platinum (Pt), lead (Pb), palladium (Pd), and alloys thereof, and nonreactive glass frit which does not react with the antireflection film at the interface between the second electrodes and the antireflection film.

The nonreactive glass frit, which serves to improve the strength of electrodes and to increase the interfacial adhesion between the second electrodes 401 and the first electrodes 301 and the interfacial adhesion between the second electrodes 401 and the antireflection film 200, may be a silica-based or phosphate-based glass frit which does not contain boron (B), bismuth (Bi) and lead (Pb). More preferably, the glass frit included in the second electrode may be a silica-based or phosphate-based glass frit which has a glass transition temperature (Tg) 1.2˜2 times of that of the glass frit included in the first electrode and which does not contain boron (B), bismuth (Bi) and lead (Pb).

The silica-based glass frit includes SiO₂, as a network forming component, and one or more selected from Li₂O, Na₂O, K₂O, MgO, CaO, BaO, SrO, ZnO, Al₂O₃, TiO₂, ZrO₂, Ta₂O₅, Sb₂O₅, HfO₂, In₂O₃, In₂O₃, Y₂O₃ and Yb₂O₃. The phosphate-based glass frit is vanadium-phosphate-based glass fit (P₂O₅—V₂O₅) or zinc-antimony-phosphate-based glass frit (P₂O₅—ZnO—Sb₂O₃). The phosphate-based glass frit may include one or more selected from K₂O, Fe₂O₃, Sb₂O₃, ZnO, TiO₂, Al₂O₃ and WO₃.

It is preferred that the second electrode material include 3˜5 wt % of the silica-based glass frit or the phosphate-based glass frit.

After the formation of the first electrodes 301 and the second electrodes 401 using the two-step printing, only the first electrodes 301 penetrate the antireflection film 200 by heat treatment to selectively connect only the first electrodes 301 with the semiconductor substrate 100.

The heat treatment is performed to make the punch through process of the first electrodes 301 and to improve the interfacial bonds between the first electrodes 301 and the second electrodes 401, the interfacial bonds between the second electrodes 401 and the antireflection film 200 and the strength of the first electrodes 301 and the second electrodes 401. The heat treatment may be performed stepwise at 100˜900° C. for several minutes.

Owing to the heat treatment of the first electrodes 301 and the second electrode 401 at 100˜900° C. after the printing thereof, the first electrodes 301 are connected with the semiconductor substrate 100 by a punch through phenomenon, and the second electrodes 401 are converted into electrodes having high density, high physical strength and excellent junction properties because the particles of the second electrodes 401 are densified and grown.

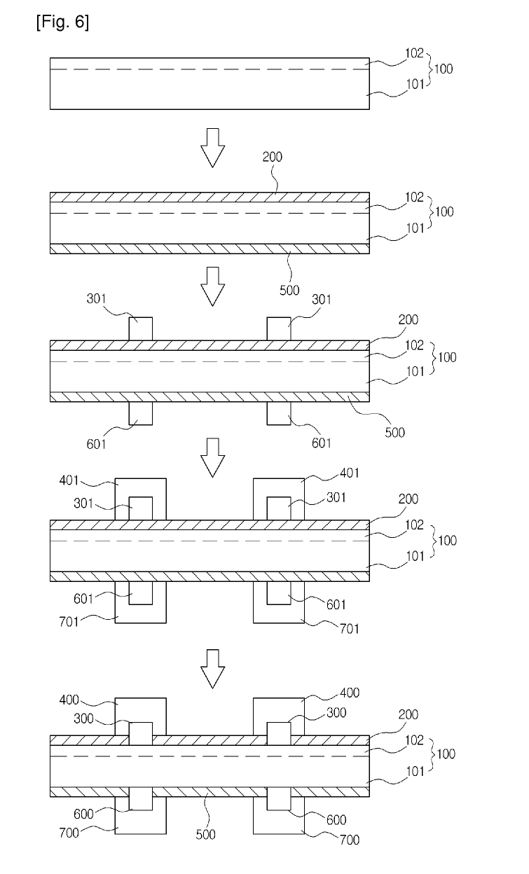

FIG. 6 is a process view showing a method of manufacturing a solar cell according to another embodiment of the present invention. The method of manufacturing a solar cell according to this embodiment is similar to that described based on FIG. 5, except that antireflection films 200 and 500 are respectively formed on both sides of the semiconductor substrate 100, preferably, on the light-receiving surface of the semiconductor substrate 100 and the opposite surface thereof. In this case, first electrodes 301 and 601 and second electrodes 401 and 701 are formed on the respective antireflection films 200 and 500 in the same manner as in FIG. 5, and then heat-treated to be respectively converted into front electrodes 300 and 400 of a solar cell and back electrodes 600 and 700 of a solar cell. In this case, unlike FIG. 6, heat treatment may be performed after first electrodes and second electrodes are formed on one antireflection film 200 and first electrodes and second electrodes are formed on the other antireflection film 500; or heat treatment may also be performed after first electrodes and second electrodes are formed on one antireflection film 200, and then heat treatment may further be performed after first electrodes and second electrodes are formed on the other antireflection film 500.

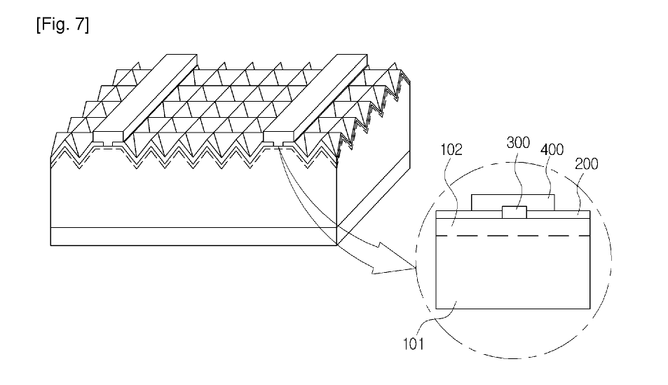

As shown in FIG. 7, the method of manufacturing a solar cell according to this embodiment may include the surface-texturing step of etching the semiconductor substrate 100 to make the surface thereof uneven before the step of forming the antireflection film. The etching of the semiconductor substrate 100 may be formed by dry etching or wet etching. The surface of the textured semiconductor substrate 100 is unevenly formed in the shape of an inverted pyramid.

Further, the method of manufacturing a solar cell according to this embodiment may include the step of applying a p-type impurity-containing doping material onto the back surface facing the light-receiving surface of the semiconductor substrate 100 and then heat-treating the semiconductor substrate 100 coated with the p-type impurity-containing doping material to form a back surface field (BSF) layer on the back surface of the semiconductor substrate 100.

Although the preferred embodiments of the present invention have been disclosed for illustrative purposes, those skilled in the art will appreciate that various modifications, additions and substitutions are possible, without departing from the scope and spirit of the invention as disclosed in the accompanying claims.

Simple modifications, additions and substitutions of the present invention belong to the scope of the present invention, and the specific scope of the present invention will be clearly defined by the appended claims.

1. A solar cell, comprising:
a semiconductor substrate having a p-n junction;
an antireflection film formed on at least one side of the semiconductor substrate;
first electrodes formed on the antireflection film; and
second electrodes covering the first electrodes, wherein only the first electrodes selectively penetrate the antireflection film and are thus connected with the semiconductor substrate by a punch through process.

2. The solar cell according to claim 1, wherein the solar cell includes antireflection films formed on both sides thereof facing each other, each of the antireflection films is a single layer film or a two-layer film, and each of the antireflection films includes the first electrodes and the second electrodes formed thereon.

3. The solar cell according to claim 2, wherein the both sides of the solar cell include a light-receiving surface and a surface opposite to the lightreceiving surface.

4. The solar cell according to claim 1, wherein the first electrodes are dot-shaped electrodes arranged at regular intervals.

5. The solar cell according to claim 4, wherein the second electrodes are band-shaped electrodes which are arranged to be spaced apart from each other, and each of the band-shaped electrodes connects two or more of the dot-shaped electrodes.

6. The solar cell according to claim 1, wherein both the first electrodes and the second electrodes are band-shaped electrodes.

7. The solar cell according to claim 6, wherein each of the first electrodes has a width of 30˜300 μm.

8. The solar cell according to claim 7, wherein each of the second electrodes has a width of 50˜1000 μm.

9. A method of manufacturing a solar cell, comprising:
forming an antireflection film on at least one side of a semiconductor substrate having a p-n junction;
applying a first electrode material penetrating the antireflection film at the time of heat treatment onto the antireflection film to form first electrodes;
applying a second electrode material not penetrating the antireflection film at the time of heat treatment onto the first electrodes to form second electrodes covering the first electrodes; and
heat-treating the semiconductor substrate provided with the first electrodes and the second electrodes to selectively connect only the first electrodes of the first electrodes and the second electrodes with the semiconductor substrate.

10. The method of manufacturing a solar cell according to claim 9, wherein, in the forming the antireflection film, the one side of the semiconductor substrate is a light-receiving surface, and an antireflection film is also formed on a surface opposite to the light-receiving surface.

11. The method of manufacturing a solar cell according to claim 10, wherein, in the forming the first electrodes and in the forming the second electrodes, the first electrodes and the second electrodes are formed on the antireflection film formed on the light-receiving surface of the solar cell and on the antireflection film formed on the surface opposite to the light-receiving surface thereof, respectively.

12. The method of manufacturing a solar cell according to claim 9, wherein the forming the first electrodes and the forming the second electrodes are each independently performed by screen printing, inkjet printing, offset printing or aerosol printing.

13. The method of manufacturing a solar cell according to claim 9, wherein, in the forming the first electrodes, the first electrodes are dot-shaped electrodes arranged at regular intervals.

14. The method of manufacturing a solar cell according to claim 13, wherein, in the forming the second electrodes, the second electrodes are band-shaped electrodes which are arranged to be spaced apart from each other, and each of the band-shaped electrodes connects two or more of the dot-shaped electrodes.

15. The method of manufacturing a solar cell according to claim 9, wherein, in the forming the first electrodes, the first electrodes are dot-shaped electrodes having a width of 30˜300 μm.

16. The method of manufacturing a solar cell according to claim 15, wherein, in the forming the second electrodes, the second electrodes are band-shaped electrodes having a width of 50˜1000 μm.

17. The method of manufacturing a solar cell according to claim 9, wherein, in the heat-treating the semiconductor substrate, the heat treatment is performed at a temperature of 100˜900° C. each of the first electrodes includes lead glass frit containing lead oxide or lead-free glass frit containing bismuth oxide and boron oxide.

19. The method of manufacturing a solar cell according to claim 18, wherein each of the second electrodes includes silica-based glass frit or phosphate-based glass frit not containing boron (B), bismuth (Bi) and lead (Pb).
